(19) United States
(12) Patent Application Publication
(10) Pub. No.: US 2024/0266154 A1
(43) Pub. Date: Aug. 8, 2024

(54) PLASMA PROCESSING APPARATUS AND SUBSTRATE SUPPORT BODY

(71) Applicant: Tokyo Electron Limited, Tokyo (JP)

(72) Inventors: Daiki HARIU, Miyagi (JP); Shinya ISHIKAWA, Miyagi (JP); Haruka ENDO, Miyagi (JP); Miyuki AOYAMA, Miyagi (JP)

(73) Assignee: Tokyo Electron Limited, Tokyo (JP)

(21) Appl. No.: 18/639,975

(22) Filed: Apr. 19, 2024

Related U.S. Application Data
(63) Continuation of application No. PCT/JP2022/038270, filed on Oct. 13, 2022.
(60) Provisional application No. 63/257,705, filed on Oct. 20, 2021.

(30) Foreign Application Priority Data
Jul. 22, 2022 (JP) 2022-117497

(51) Int. Cl. H01J 37/32

(52) U.S. Cl. CPC H01J 37/32715; H01J 37/32513; H01J 2237/2005; H01J 2237/2007

(57) ABSTRACT

A plasma processing apparatus includes: a plasma processing chamber; a base support disposed within the plasma processing chamber; a base having a first through hole penetrating from an upper surface of the base to a lower surface of the base and disposed on the base support; an electrostatic chuck having a second through hole communicating with the first through hole by penetrating from a substrate support surface or a ring support surface to a lower surface of the electrostatic chuck and disposed on the base; a first insulating member disposed within the first through hole; a second insulating member disposed within the first through hole to surround at least a portion of the first insulating member; a first sealing member disposed between the first insulating member and the electrostatic chuck; and a second sealing member disposed between the first insulating member and an insulating support member.

### CROSS-REFERENCE TO RELATED APPLICATIONS

This application is a bypass continuation application of International Patent Application No. PCT/JP2022/038270 having an international filing date of Oct. 13, 2022 and designating the United States, the international application being based upon and claiming the benefit of priority from U.S. Patent Application No. 63/257,705 and Japanese Patent Application No. 2022-117497, filed on Oct. 20, 2021 and Jul. 22, 2022, respectively, the entire contents of each are incorporated herein by reference.

### TECHNICAL FIELD

The present disclosure relates to a plasma processing apparatus and a substrate support body.

### BACKGROUND

Patent document 1 discloses a stage, including a wafer placement part having a placement surface on which a wafer is placed and a first through hole formed therein, a base bonded to a rear surface of the wafer placement part by a first adhesive layer and having a second through hole, the second through hole having a hole diameter larger than a hole diameter of the first through hole and communicating with the first through hole, a cylindrical sleeve installed inside the second through hole to be detachable from the base together with a sealing member, and the sealing member installed between the rear face of the wafer placement part and the sleeve to be separated from the first adhesive layer so as to seal the first adhesive layer. A convex part is formed to extend on at least one of an outer circumference or an inner circumference of a tip end of the sleeve. The sealing member is pressed against a tip end surface of the sleeve to expand and contract.

### PRIOR ART DOCUMENTS

### Patent Documents

Patent Document 1: Japanese Patent Laid-Open Publication No. 2021-28958

### SUMMARY

According to one embodiment of the present disclosure, there is provided a plasma processing apparatus, including: a plasma processing chamber; a base support disposed within the plasma processing chamber; a base having a first through hole penetrating from an upper surface of the base to a lower surface of the base and disposed on an upper portion of the base support; an electrostatic chuck having a second through hole communicating with the first through hole by penetrating from a substrate support surface or a ring support surface to a lower surface of the electrostatic chuck and disposed on an upper portion of the base; a first insulating member having a cylindrical shape and disposed within the first through hole; a second insulating member having a cylindrical shape and disposed within the first through hole to surround at least a portion of the first insulating member; a first sealing member disposed between the first insulating member and the electrostatic chuck; and a second sealing member disposed between the first insulating member and an insulating support member disposed within the base support.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an example of a view illustrating a configuration example of a plasma processing apparatus.

FIG. 2 is an example of a cross-sectional view of a substrate support around a lifter pin.

FIG. 3 is an example of a cross-sectional view of a main body.

FIG. 4 is an example of an exploded view of the main body.

FIG. 5 is an example of a cross-sectional view schematically illustrating a cross-section A-A in FIG. 3.

FIG. 6 is another example of the cross-sectional view of a substrate support around a lifter pin.

FIG. 7 is still another example of the cross-sectional view of the substrate support around the lifter pin.

FIG. 8 is still another example of the cross-sectional view of the substrate support around the lifter pin.

FIG. 9 is an example of a cross-sectional view of the substrate support around a gas supply path.

FIG. 10 is another example of the cross-sectional view of the substrate support around the gas supply path.

FIG. 11 is an example of a cross-sectional view of the substrate support around a sensor.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In each of the drawings, the same or corresponding parts are denoted by like reference symbols.

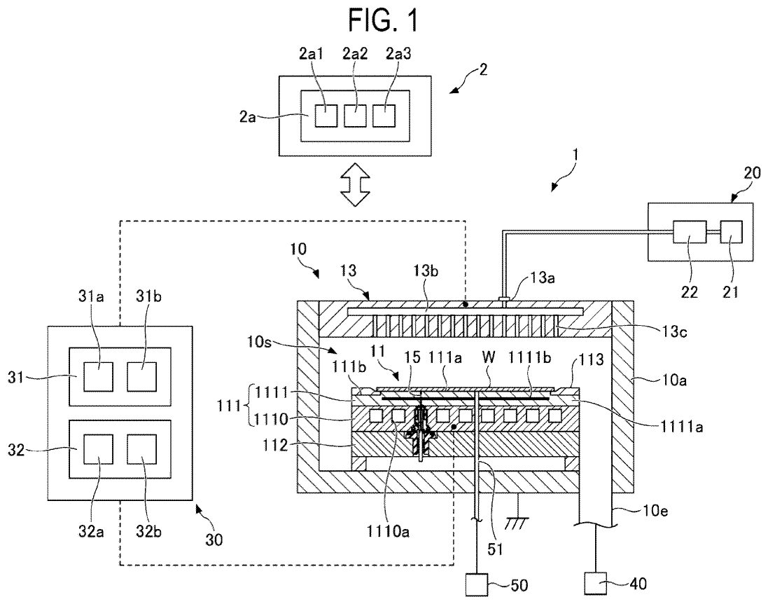

Hereinafter, a configuration example of a plasma processing system will be described. FIG. 1 is an example of a view illustrating a configuration example of a capacitively coupled plasma processing apparatus.

The plasma processing system includes a capacitively coupled plasma processing apparatus 1 and a controller 2. The capacitively coupled plasma processing apparatus 1 includes a plasma processing chamber 10, a gas supply 20, a power source 30, and an exhaust system 40. The plasma processing apparatus 1 also includes a substrate support 11 and a gas introducer. The gas introducer is configured to introduce at least one processing gas into the plasma processing chamber 10. The gas introducer includes a shower head 13. The substrate support 11 is disposed within the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 has at least one gas supply port for supplying at least one processing gas to the plasma processing space 10s and at least one gas exhaust port for discharging a gas from the plasma processing space 10s. The plasma processing chamber 10 is grounded. The shower head 13 and the substrate support 11 are electrically insulated from a housing of the plasma processing chamber 10.

The substrate support 11 includes a substrate support body (main body) 111, a base support 112, and a ring assembly 113. The substrate support body 111 has a central region 111a for supporting a substrate W and an annular region 111b for supporting the ring assembly 113. A wafer is an example of the substrate W. The annular region 111b of the substrate support body 111 surrounds the central region 111a of the substrate support body 111 in a plan view. The substrate W is disposed on the central region 111a of the substrate support body 111, and the ring assembly 113 is disposed on the annular region 111b of the substrate support body 111 so as to surround the substrate W on the central region 111a of the substrate support body 111. Therefore, the central region 111a is also called a substrate support surface for supporting the substrate W, and the annular region 111b is also called a ring support surface for supporting the ring assembly 113.

In one embodiment, the substrate support body 111 includes a base 1110 and an electrostatic chuck 1111. The base 1110 includes a conductive member. The conductive member of the base 1110 functions as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 113 may be disposed on the annular electrostatic chuck or the annular insulating member or may be disposed on both sides of the electrostatic chuck 1111 and the annular insulating member. Furthermore, at least one radio frequency (RF)/direct current (DC) electrode coupled to an RF power source 31 and/or a DC power source 32, which will be described later, may be disposed within the ceramic member 1111a. In this case, the at least one RF/DC electrode functions as the lower electrode. The RF/DC electrode is also referred to as a bias electrode when a bias RF signal and/or DC signal described later is supplied to the at least one RF/DC electrode. In addition, the conductive member of the base 1110 and the at least one RF/DC electrode may function as a plurality of lower electrodes. Further, the electrostatic electrode 1111b may function as the lower electrode. Therefore, the substrate support 11 includes at least one lower electrode.

The base support 112 is disposed within the plasma processing chamber 10. The base 1110 is disposed on the base support 112. The base support 112 includes a conductive member. The substrate support body 111 is detachably attached to the base support 112.

The ring assembly 113 includes one or more annular members. In one embodiment, the one or more annular members include one or more edge rings and at least one cover ring. The edge ring is made of a conductive material or an insulating material, and the cover ring is made of an insulating material.

Further, the substrate support 11 may include a temperature adjustment module configured to adjust a temperature of at least one of the electrostatic chuck 1111, the ring assembly 113, and the substrate to a target temperature. The temperature adjustment module may include a heater, a heat transfer medium, a flow path 1110a, or a combination thereof. A heat transfer fluid such as brine or gas flows through the flow path 1110a. In one embodiment, the flow path 1110a is formed within the base 1110, and one or more heaters are disposed within the ceramic member 1111a of the electrostatic chuck 1111. Further, the substrate support 11 may include a heat transfer gas supply 50 configured to supply a heat transfer gas to a gap between a rear surface of the substrate W and the central region 111a via a gas supply path 51. Further, the substrate support 11 may include a heat transfer gas supply (not shown) configured to a heat transfer gas to a gap between a rear surface of at least one annular member (e.g., edge ring) of the ring assembly 113 and the annular region 111b via a gas supply path (not shown).

Further, the substrate support 11 may include, for example, three lifter pins 15 that can be raised and lowered from a substrate support surface of the central region 111a. The lifter pins 15 are raised or lowered by a lifting mechanism (not shown). As the lifter pins 15 are raised from the substrate support surface, the substrate W placed on the substrate support surface is lifted by the lifter pins 15. Thereby, a transfer device (not shown) receives the substrate W lifted by the lifter pins 15. Further, the transfer device delivers the substrate W to the lifter pins 15. Further, as the lifter pins 15 is lowered on the substrate support surface, the substrate W supported by the lifter pins 15 is delivered to the substrate support surface.

Further, the substrate support 11 may include, for example, three lifter pins (not shown) that can be raised and lowered from a ring support surface of the annular region 111b. The lifter pins are raised or lowered by a lifting mechanism (not shown). As the lifter pins are raised from the ring support surface, at least one annular member (e.g., an edge ring) of the ring assembly 113 placed on the ring support surface is lifted by the lifter pins. Thereby, a transfer device (not shown) receives the annular member lifted by the lifter pins. Further, the transfer device delivers the annular member to the lifter pins. Further, as the lifter pins are lowered on the ring support surface, the annular member supported by the lifter pins is transferred to the ring support surface.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. The shower head 13 also includes at least one upper electrode. The gas introducer may include, in addition to the shower head 13, one or plural side gas injectors (SGI) attached to one or more openings formed in the side wall 10a.

The gas supply 20 may include at least one gas source 21 and at least one flow rate controller 22. In one embodiment, the gas supply 20 is configured to supply at least one processing gas from a corresponding gas source 21 to the shower head 13 via a corresponding flow rate controller 22. Each flow rate controller 22 may include, for example, a mass flow controller or a pressure-controlled flow rate controller. Additionally, the gas supply 20 may include one or more flow rate modulation devices that modulate or pulse a flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Thereby, plasma is formed from at least one processing gas supplied to the plasma processing space 10s. Accordingly, the RF power source 31 may function as at least a part of a plasma generator configured to generate plasma from one or more processing gases in the plasma processing chamber 10. Further, by supplying a bias RF signal to at least one lower electrode, a bias potential is generated in the substrate W, and an ion component in the formed plasma can be drawn into the substrate W.

In one embodiment, the RF power source 31 includes a first RF generator 31a and a second RF generator 31b. The first RF generator 31a is configured to generate a source RF signal (source RF power) for plasma generation by being coupled to at least one lower electrode and/or at least one upper electrode via at least one impedance matching circuit. In one embodiment, the source RF signal has a frequency within a range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to generate a bias RF signal (bias RF power) by being coupled to at least one lower electrode via at least one impedance matching circuit. The frequency of the bias RF signal may be equal to or different from the frequency of the source RF signal. In one embodiment, the bias RF signal has a lower frequency than the frequency of the source RF signal. In one embodiment, the bias RF signal has a frequency within a range of 100 kHz to 60 MHz. In one embodiment, the second RF generator 31b may be configured to generate a plurality of bias RF signals having different frequencies. The generated one or plural bias RF signals are supplied to at least one lower electrode. In various embodiments, at least one of the source RF signal or the bias RF signal may be pulsed.

In addition, the power source 30 may also include the DC power source 32 coupled to the plasma processing chamber 10. The DC power source 32 includes a first DC generator 32a and a second DC generator 32b. In one embodiment, the first DC generator 32a is configured to generate a first DC signal by being connected to at least one lower electrode. The generated first bias DC signal is applied to at least one lower electrode. In one embodiment, the second DC generator 32b is configured to generate a second DC signal by being connected to at least one upper electrode. The generated second DC signal is applied to the at least one upper electrode.

In various embodiments, at least one of the first DC signal or the second DC signal may be pulsed. In this case, a sequence of voltage pulses is applied to at least one lower electrode and/or at least one upper electrode. The voltage pulses may have a rectangular, trapezoidal, or triangular pulse waveform, or a combination thereof. In one embodiment, a waveform generator for generating the voltage pulse sequence from a DC signal is connected between the first DC generator 32a and at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulses may have positive polarity or negative polarity. Furthermore, the voltage pulse sequence may include one or plural positive-polarity voltage pulses and one or plural negative-polarity voltage pulses within one cycle. The first and second DC generators 32a and 32b may be installed in addition to the RF power source 31, or the first DC generator 32a may be installed instead of the second RF generator 31b.

The exhaust system 40 may be connected to, for example, a gas discharge port 10e formed at a bottom portion of the plasma processing chamber 10. The exhaust system 40 may include a pressure regulation valve and a vacuum pump. Pressure in the plasma processing space 10s is regulated by the pressure regulation valve. The vacuum pump may include a turbomolecular pump, a dry pump, or a combination thereof.

The controller 2 processes computer-executable instructions that cause the plasma processing apparatus 1 to perform various steps described in the present disclosure. The controller 2 may be configured to control each element of the plasma processing apparatus 1 so as to perform various steps described herein. In one embodiment, a part or all of the controller 2 may be included in the plasma processing apparatus 1. The controller 2 may include a processor 2a1, a memory 2a2, and a communication interface 2a3. The controller 2 is implemented by, for example, a computer 2a. The processor 2a1 may be configured to read out a program from the memory 2a2 and perform various control operations by executing the read-out program. This program may be pre-stored in the memory 2a2 or may be acquired via a medium when necessary. The acquired program is stored in the memory 2a2 and is read out from the memory 2a2 by the processor 2a1. The medium may be various storage media readable by the computer 2a or may be a communication line connected to the communication interface 2a3. The processor 2a1 may be a central processing unit (CPU). The memory 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

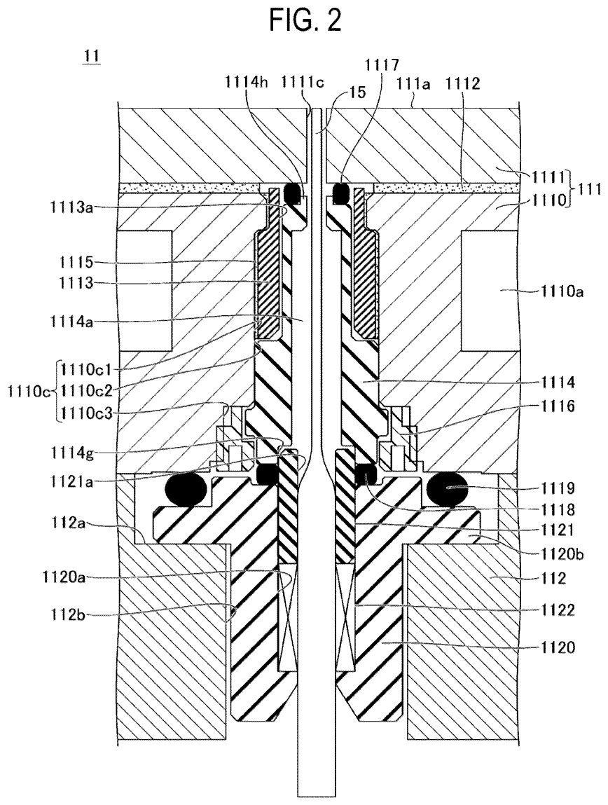

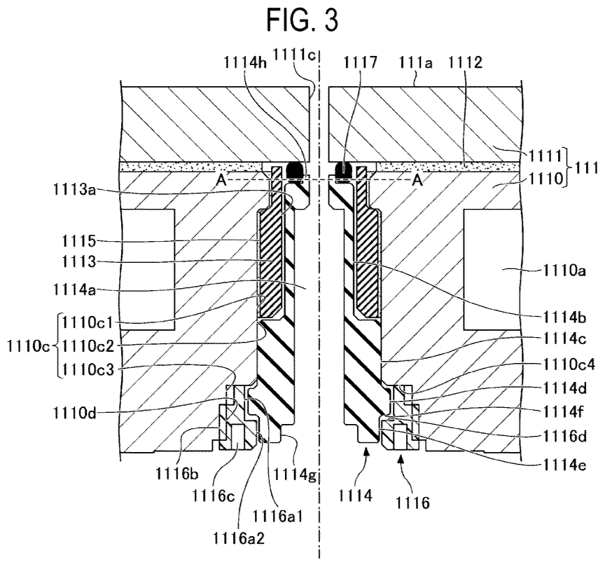

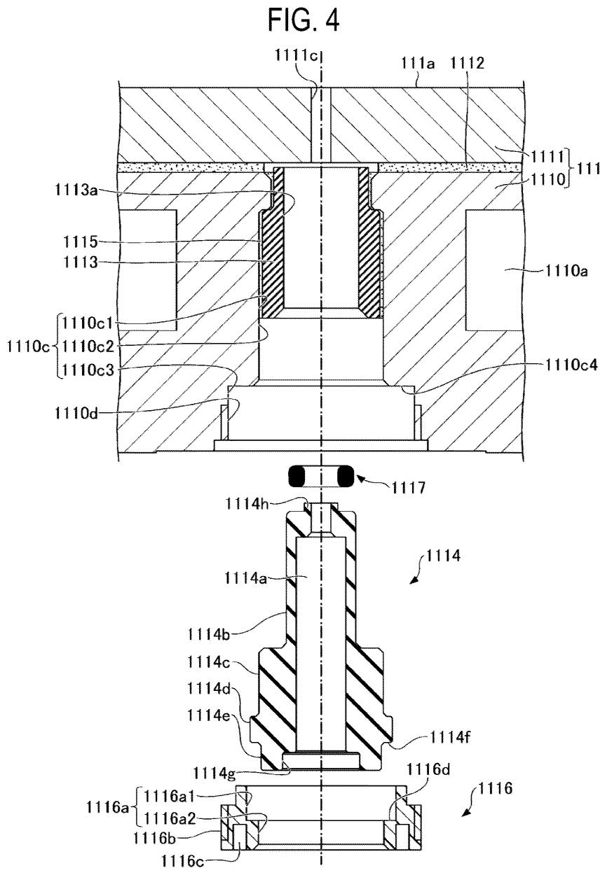

Next, the structure of the substrate support 11 will further be described with reference to FIGS. 2 to 4. FIG. 2 is an example of a cross-sectional view of the substrate support 11 around the lifter pin 15. FIG. 3 is an example of a cross-sectional view of the substrate support body 111. FIG. 4 is an example of an exploded view of the substrate support body 111.

The substrate support 11 includes the substrate support body 111 and the base support 112, and the substrate support body 111 is disposed on the base support 112. The substrate support body 111 includes the base 1110, the electrostatic chuck 1111, and an adhesive layer 1112, and the electrostatic chuck 1111 is disposed on the base 1110 via the adhesive layer 1112. The adhesive layer 1112 is disposed between the base 1110 and the electrostatic chuck 1111 and adheres an upper surface of the base 1110 to a lower surface of the electrostatic chuck 1111. Thereby, the electrostatic chuck 1111 is fixed to the base 1110. The adhesive layer 1112 is made of a material having plasma resistance and heat resistance. The material having plasma resistance and heat resistance includes, for example, acrylic resin, silicone (silicon resin), and epoxy resin.

The electrostatic chuck 1111 has a second through hole 1111c that penetrates from an upper surface (the substrate support surface of the central region 111a) to the lower surface of the electrostatic chuck 1111. The lifter pin 15 is inserted through the second through hole 1111c.

The base 1110 has a first through hole 1110c that penetrates from the upper surface of the base 1110 to a lower surface of the base 1110 and communicates with the second through hole 1111c of the electrostatic chuck 1111. The lifter pin 15 is inserted through the first through hole 1110c. Further, an outer sleeve (a second insulating member) 1113, an inner sleeve (a first insulating member) 1114, an adhesive layer 1115, and a lid member 1116 are disposed in the first through hole 1110c. Further, the first through hole 1110c includes, from the upper surface of the base 1110 to the lower surface of the base 1110, an outer sleeve placement portion 1110c1, an inner sleeve contact portion 1110c2, and a lid member placement portion 1110c3.

The outer sleeve 1113 is a tubular (e.g., cylindrical) member having a through hole 1113a and is made of an insulating member such as ceramic. The outer sleeve 1113 is disposed within the first through hole 1110c. At least a portion of the inner sleeve 1114 is inserted into the through hole 1113a of the outer sleeve 1113. Thereby, the outer sleeve 1113 is disposed within the first through hole 1110c so as to surround at least a portion of the inner sleeve 1114. The adhesive layer 1115 is disposed between the base 1110 and the outer sleeve 1113 and adheres an outer circumferential surface of the outer sleeve 1113 and an inner circumferential surface of the outer sleeve placement portion 1110c1. Thereby, the outer sleeve 1113 is fixed to the base 1110. The adhesive layer 1115 is made of a material having plasma resistance and heat resistance. For example, the material having plasma resistance and heat resistance includes acrylic resin, silicone (silicon resin), and epoxy resin.

The inner sleeve 1114 is a tubular (e.g., cylindrical) member having a through hole 1114a and is made of an insulating member such as ceramic. The inner sleeve 1114 is disposed within the first through hole 1110c. The lifter pin 15 is inserted into the through hole 1114a. The inner sleeve 1114 has a shape in which cylinders having different diameters are stacked in an axial direction. That is, the inner sleeve 1114 includes, from the upper surface to the lower surface of the base 1110, an insertion portion (a first portion) 1114b having a first outer diameter, an axis alignment portion (a second portion) 1114c having a second outer diameter larger than the first outer diameter, an enlarged diameter portion (a third portion) 1114d having a third outer diameter larger than the second outer diameter, and a reduced diameter portion (a fourth portion) 1114e having a fourth outer diameter smaller than the third outer diameter.

The insertion portion 1114b is inserted into the through hole 1113a of the outer sleeve 1113. Further, a gap may be formed between an inner circumferential surface of the through hole 1113a and an outer circumferential surface of the insertion portion 1114b. Thereby, the outer sleeve 1113 is disposed within the first through hole 1110c so as to surround the insertion portion 1114b of the inner sleeve 1114.

The axis alignment portion 1114c is formed with a larger diameter than the insertion portion 1114b and is inserted into the inner sleeve contact portion 1110c2. Here, as an inner circumferential surface of the inner sleeve contact portion 1110c2 and the axis alignment portion 1114c come into contact, an axis position of the inner sleeve 1114 is aligned with the first through hole 1110c. Thereby, the axial position of the inner sleeve 1114 can be determined with respect to the first through hole 1110c of the base 1110, so that alignment accuracy of the axial position of the inner sleeve 1114 can be improved.

The enlarged diameter portion 1114d is formed to have a larger diameter than the axis alignment portion 1114c. The reduced diameter portion 1114e is formed to have a smaller diameter than the enlarged diameter portion 1114d. Further, an annular locking surface 1114f is formed between the enlarged diameter portion 1114d and the reduced diameter portion 1114e.

In addition, the inner sleeve 1114 has a fitting portion 1114g that communicates with the through hole 1113a and fits into a lifter pin guide 1121 which will be described later.

The inner sleeve 1114 also has a protrusion 1114h for aligning a seal ring 1117 which will be described later.

The lid member 1116 is a substantially cylindrical (e.g., cylindrical) member having a through hole 1116a through which the lifter pin 15 is inserted and is made of, for example, a resin member such as polyetheretherketone (PEEK). The lid member 1116 is disposed in a lid member placement portion 1110c3 of the first through hole 1110c.

The through hole 1116a includes a large diameter hole portion 1116a1 and a small diameter hole portion 1116a2 from the upper surface to the lower surface of the base 1110. The enlarged diameter portion 1114d of the inner sleeve 1114 is disposed in the large diameter hole portion 1116a1. The large diameter hole portion 1116a1 is formed larger in a radial direction than the enlarged diameter portion 1114d of the inner sleeve 1114. Further, the depth of the large diameter hole portion 1116a1 is formed deeper in an axial direction than the length of the enlarged diameter portion 1114d of the inner sleeve 1114. The reduced diameter portion 1114e of the inner sleeve 1114 is disposed in the small diameter hole portion 1116a2. The small diameter hole portion 1116a2 is formed smaller in the radial direction than the enlarged diameter portion 1114d of the inner sleeve 1114 and larger in the radial direction than the reduced diameter portion 1114e of the inner sleeve 1114. Further, an annular locking surface 1116d is formed between the large diameter hole portion 1116a1 and the small diameter hole portion 1116a2.

Here, the lid member placement portion 1110c3 is formed to have a diameter larger than a diameter of the inner sleeve contact portion 1110c2, and an annular ceiling surface 1110c4 is formed between the inner sleeve contact portion 1110c2 and the lid member placement portion 1110c3. Furthermore, when the lid member 1116 is attached to the base 1110, an axial length from the ceiling surface 1110c4 to the locking surface 1116d is longer than an axial length of the enlarged diameter portion 1114d of the inner sleeve 1114.

A circumferential surface of the lid member placement portion 1110c3 has a female thread portion 1110d formed with a female thread. Further, the surface of the female thread portion 1110d is alumite-processed.

An outer circumferential surface of the lid member 1116 has a male thread portion 1116b formed with a male thread. Furthermore, a jig hole 1116c for inserting a jig (not shown) is formed in a bottom surface of the lid member 1116. By inserting the jig into the jig hole 1116c and rotating the lid member 1116, the female thread portion 1110d of the base 1110 and the male thread portion 1116b of the lid member 1116 are screwed together, and thus, the lid member 1116 is fixed to the base 1110.

In the base support 112, a recessed portion 112a and a through hole 112b are formed. The recessed portion 112a is formed on the upper surface of the base support 112. The through hole 112b communicates with the recessed portion 112a and penetrates from the upper surface (a bottom surface of the recessed portion 112a) to the lower surface of the base support 112. A support member 1120 is disposed in the recessed portion 112a and the through hole 112b. The support member 1120 is formed of an insulating member such as ceramic. The support member 1120 has a cylindrical portion having a through hole 1120a through which the lifter pin 15 is inserted, and a flange 1120b. The cylindrical portion below the flange 1120b is inserted into the through hole 112b, and the flange 1120b and a cylindrical portion above the flange 1120b are disposed in the recessed portion 112a. Since a lower surface of the flange 1120b and the bottom surface of the recessed portion 112a are in contact with each other, the position of the support member 1120 in a height direction is aligned. Further, a gap may be formed between an inner peripheral surface of the through hole 112b and an outer circumferential surface of the cylindrical portion below the flange 1120b.

The lifter pin guide 1121 and a lifter pin seal portion 1122 are disposed in the through hole 1120a of the support member 1120.

The lifter pin guide 1121 is a tubular (e.g., cylindrical) member having a through portion 1121a through which the lifter pin 15 is inserted and is made of a resin member such as polytetrafluoroethylene (PTFE). By fitting an upper portion of the lifter pin guide 1121 into the fitting portion 1114g of the inner sleeve 1114, an axial position of the lifter pin guide 1121 is aligned with the inner sleeve 1114. Further, by inserting the lifter pin 15 into the through portion 1121a of the lifter pin guide 1121, an axial position of the lifter pin 15 is aligned with the lifter pin guide 1121.

The lifter pin seal portion 1122 provides a vacuum seal between an inner peripheral surface of the through hole 1120a of the support member 1120 and an outer peripheral surface of the lifter pin 15.

The seal ring (a first sealing member) 1117 is held between a lower surface of the electrostatic chuck 1111 and an upper surface of the inner sleeve 1114. A seal ring (a second sealing member) 1118 is held between a lower surface of the inner sleeve 1114 and an upper surface of the support member 1120. The seal rings 1117 and 1118 are, for example, O-rings. The seal rings 1117 and 1118 have an annular shape and are made of a material that is resistant to a radical. For the seal rings 1117 and 1118, a fluorine-based material such as vinylidene fluoride (FKM), polytetrafluoroethylene (PTFE), or tetrafluoroethylene-perfluoro vinyl ether (FFKM) can be used.

A seal ring (a third sealing member) 1119 is held between a bottom surface of the base 1110 and an upper surface of the flange 1120b of the support member 1120. The seal ring 1119 is, for example, an O-ring. The seal ring 1119 has an annular shape and may be made of a material that can ensure sealing performance even in a low temperature range of −120 degrees C. to 250 degrees C. The seal ring 1119 can be made of, for example, vinyl methyl silicone rubber (VMQ) or vinylidene fluoride (FKM).

Here, the substrate support 11 during plasma processing will be described with reference to FIG. 2. The plasma processing space 10s (see FIG. 1) of the plasma processing chamber 10 is in a vacuum atmosphere. Here, the through holes (the second through hole 1111c and the first through hole 1110c) through which the lifter pin 15 installed in the substrate support body 111 is inserted are blocked from an atmospheric space by the seal ring 1119 and the lifter pin seal portion 1122.

Furthermore, when plasma is generated in the plasma processing space 10s (see FIG. 1) of the plasma processing chamber 10, a radical and the like enter the through holes (the second through hole 1111c and first through hole 1110c) through which the lifter pin 15 is inserted. Here, by providing the seal ring 1117 between the lower surface of the electrostatic chuck 1111 and the upper surface of the inner sleeve 1114, it is possible to prevent the adhesive layers 1112 and 1115 from being consumed by the radical. Further, by providing the seal ring 1118 between the lower surface of the inner sleeve 1114 and the upper surface of the support member 1120, it is possible to prevent the adhesive layer 1115 and the seal ring 1119 from being consumed by the radical. Here, as the adhesive layer 1112 is consumed by the radical or the like, heat dissipation performance (thermal conduction) from the electrostatic chuck 1111 to the base 1110 decreases in a place in which the adhesive layer 1112 is consumed, and thus, there is a risk that in-plane uniformity of the temperature of the substrate W may deteriorate. In contrast, in the substrate support body 111, the seal rings 1117 and 1118 prevent the adhesive layer 1112 from being consumed, thereby preventing deterioration of heat dissipation performance from the electrostatic chuck 1111 to the base 1110 due to consumption of the adhesive layer 1112 and improving in-plane uniformity of the temperature of the substrate W supported by the substrate support body 111.

Furthermore, the inner sleeve 1114 is disposed in the first through hole 1110c (the through hole 1113a, the inner sleeve contact portion 1110c2, and the through hole 1116a) so as to be movable in a vertical direction. That is, the inner sleeve 1114 is disposed between the lower surface of the electrostatic chuck 1111 and the upper surface of the support member 1120, the elastically deformable seal ring 1117 is disposed between the lower surface of the electrostatic chuck 1111 and the upper surface of the inner sleeve 1114, and the elastically deformable seal ring 1118 is disposed between the upper surface of the support member 1120 and the lower surface of the inner sleeve 1114. The inner sleeve 1114 rests at a position in a height direction at which elastic forces of the elastically deformable seal rings 1117 and 1118 are balanced.

For example, when plasma is generated in the plasma processing space 10s (see FIG. 1) of the plasma processing chamber 10, the temperature of an upper surface side of the substrate support body 111 becomes higher than the temperature of a lower surface side of the substrate support body 111 due to heat of the plasma. On the other hand, on the lower surface side of the substrate support body 111, the base 1110 is cooled by a heat transfer fluid flowing through the flow path 1110a. As a result, the temperature of the lower surface side of the substrate support body 111 becomes lower than the temperature of the upper surface side of the substrate support body 111. In this way, in a state in which there is a temperature difference between the upper surface side and the lower surface side of the substrate support body 111, the seal ring 1117 expands compared to the seal ring 1118, and the seal ring 1118 contracts compared to the seal ring 1117. The expansion and contraction of the seal rings 1117 and 1118 cause the inner sleeve 1114 to move in the vertical direction. In this example, as the seal ring 1117 expands, the inner sleeve 1114 moves downward. As the inner sleeve 1114 moves downward, the seal ring 1118 contracts and is stabilized so as to balance elastic force caused by the expansion of the seal ring 1117. As a result, the position of the inner sleeve 1114 follows elastic deformation of the seal rings 1117 and 1118, thereby absorbing positional fluctuations caused by the heat of plasma processing and expanding a usable temperature range of the substrate support body 111.

Here, in a configuration in which the axial position of the inner sleeve is aligned by disposing the outer sleeve in the through hole of the base and disposing the inner sleeve in the through hole of the outer sleeve, tolerance between the base and the outer sleeve, tolerance between the outer sleeve and the inner sleeve, and an error in a film thickness of the adhesive layer between the base and the outer sleeve overlap, thereby resulting in a deterioration in alignment accuracy of the axial position of the inner sleeve. In contrast, in the substrate support body 111, the axial position of the inner sleeve 1114 is aligned by the inner sleeve contact portion 1110c2 formed in the first through hole 1110c of the base 1110 and the axis alignment portion 1114c of the inner sleeve 1114. Thereby, the axial position of the inner sleeve 1114 can be aligned with high accuracy. Furthermore, tolerance related to alignment of the axial position of the inner sleeve 1114 is easily calculated.

Further, as shown in FIG. 3, when the substrate support body 111 is removed from the base support 112, the locking surface 1114f of the inner sleeve 1114 is locked with the locking surface 1116d of the lid member 1116, so that the inner sleeve 1114 can be prevented from falling from the first through hole 1110c. Thereby, workability when attaching or detaching the substrate support body 111 to or from the base support 112 can be improved. Moreover, the lid member 1116 can be formed with low cost.

Further, the female thread portion 1110d of the base 1110 is alumite-processed. Accordingly, in the base 1110 to which the RF signal is applied, electric discharge can be suppressed by alumite-processing the surface of the female thread portion 1110d to form an insulating layer on the surface of the female thread portion 1110d. Further, by forming, of a resin material, the lid member 1116 having the male thread portion 1116b screwed into the female thread portion 1110d, peeling of the insulating layer can be prevented.

Further, as shown in FIG. 2, the lifter pin guide 1121 is fitted with the fitting portion 1114g of the inner sleeve 1114, so that the axial position of the lifter pin guide 1121 is aligned. Thereby, alignment accuracy of the axial position of the lifter pin 15 guided by the lifter pin guide 1121 can be improved. As a result, the lifter pin 15 can be prevented from contacting the electrostatic chuck 1111 (a bottom surface of the electrostatic chuck 1111 and a wall surface of the second through hole 1111c).

Further, the protrusion 1114h formed on the inner sleeve 1114 enters a hole inside the seal ring 1117, so that the seal ring 1117 is aligned. Thereby, the lifter pin 15 can be prevented from contacting the seal ring 1117.

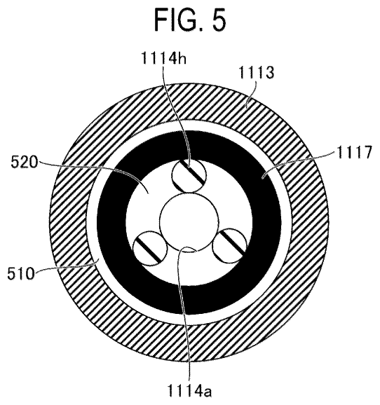

The protrusion 1114h of the inner sleeve 1114 will further be described with reference to FIG. 5. FIG. 5 is an example of a cross-sectional view schematically illustrating cross-section A-A in FIG. 3.

A plurality of protrusions 1114h is formed in a circumferential direction. For example, three protrusions 1114h are formed at equal intervals of 120 degrees in the circumferential direction. The protrusion 1114h has a circular cross section and has, for example, a diameter of 1.2 mm and a height of 0.65 mm The protrusions 1114h shown in FIG. 5 are exemplary and do not have to be disposed at equal intervals. Further, the number of protrusions 1114h may be four or more. The cross section of the protrusion 1114h is not limited to a circular shape and may be an elliptical shape, a triangular shape, a quadrangular shape, or the like.

The seal ring 1117 is disposed between the protrusion 1114h and the outer sleeve 1113. The seal ring 1117 is disposed so as to be in contact with the protrusion 1114h on an inner circumference of the seal ring 1117. A space 510 is formed between an outer circumference of the seal ring 1117 and the outer sleeve 1113. Further, a space (filling rate relaxation region) 520 is formed between each of the protrusions 1114h. Thereby, when the seal ring 1117 expands, the seal ring 1117 can expand into the space 510 and the space 520. In other words, by providing the space 520, a filling rate of the seal ring 1117 can be lowered. Thereby, a usable temperature range of the substrate support body 111 can be expanded.

Furthermore, the seal ring 1117, the inner sleeve 1114, and the outer sleeve 1113 have different coefficients of linear expansion, and the coefficient of linear expansion of the seal ring 1117 is larger than the coefficients of linear expansion of the inner sleeve 1114 and the outer sleeve 1113. For example, a coefficient of linear expansion of a fluorine-based material forming the seal ring 1117 is approximately 3.15×10⁻⁴(/K), and a coefficient of linear expansion of ceramic forming the inner sleeve 1114 and the outer sleeve 1113 is approximately 7.60×10⁻⁶(/K). For this reason, when a cylindrical shape is formed on an upper portion of the inner sleeve 1114 in contact with the inner circumference of the seal ring 1117, if a certain temperature change occurs, there is a risk that the electrostatic chuck 1111, the inner sleeve 1114, and the outer sleeve 1113 may be crushed due to thermal expansion and thermal contraction of the seal ring 1117.

In contrast, in the substrate support body 111, the protrusions 1114h are formed on the upper portion of the inner sleeve 1114 to form the space 520 between each of the protrusions 1114h. As a result, even when the seal ring 1117 thermally expands or contracts due to a temperature change, pressure applied to the electrostatic chuck 1111, the inner sleeve 1114, and the outer sleeve 1113 can be reduced by the space 520, and the electrostatic chuck 1111, the inner sleeve 1114, and outer sleeve 1113 can be prevented from being crushed.

Further, by providing the protrusions 1114h on the upper portion of the inner sleeve 1114, alignment tolerance when the seal ring 1117 is installed around the inner sleeve 1114 can be reduced.

Furthermore, when the protrusions 1114h become worn out, the lid member 1116 can be removed from the substrate support body 111 and the inner sleeve 1114 can be easily replaced, so that maintainability of the substrate support body 111 can be improved.

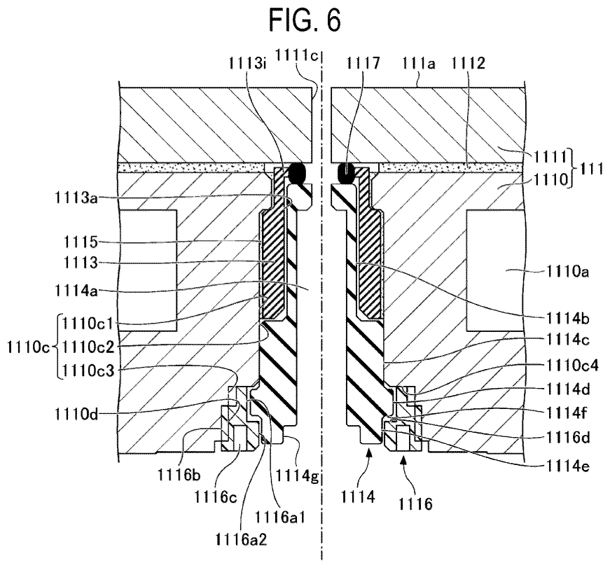

In FIGS. 2 to 5, the seal ring 1117 has been described as having a configuration in which the seal ring 1117 is aligned by contacting the protrusions 1114h of the inner sleeve 1114 on the inner circumference of the seal ring 1117. However, the configuration of the seal ring 1117 is not limited thereto. FIG. 6 is another example of a cross-sectional view of the substrate support 11 around the lifter pin 15.

The substrate support 11 shown in FIG. 6 is different in that the protrusion 1114h of the inner sleeve 114 is not formed, and the outer sleeve 1113 has a protrusion 1113i that protrudes inward. The other configurations are the same, and a redundant description is omitted. As a result, the seal ring 1117 is aligned by contacting the protrusion 1113i of the outer sleeve 1113 on the outer circumference of the seal ring 1117.

In FIGS. 2 to 6, the inner sleeve 1114 and the lifter pin guide 1121 have been described as being separate bodies. However, the configurations of the inner sleeve 1114 and the lifter pin guide 1121 are not limited thereto.

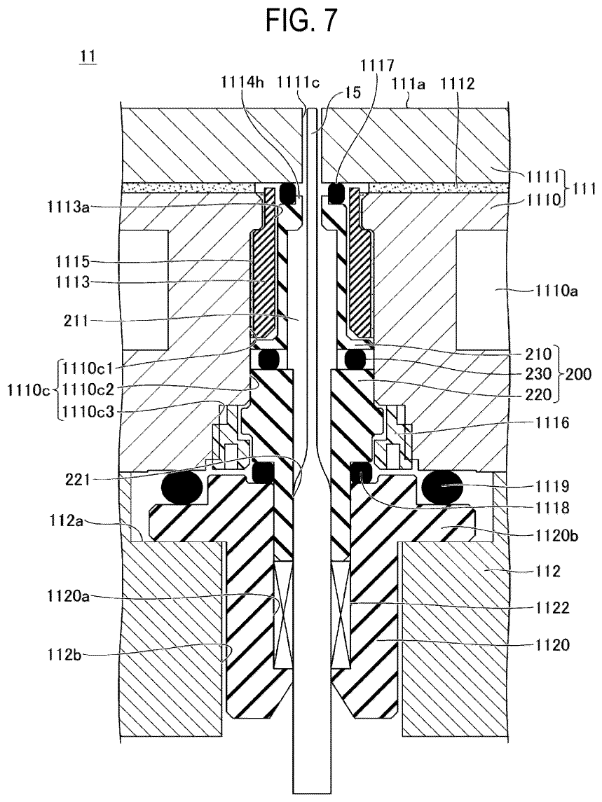

FIG. 7 is still another example of the cross-sectional view of the substrate support 11 around the lifter pin 15. The substrate support body 111 shown in FIG. 7 includes an inner sleeve 200 instead of the inner sleeve 1114 and lifter pin guide 1121 shown in FIG. 2. The other configurations are the same, and a redundant description is omitted.

The inner sleeve 200 includes an inner sleeve upper portion 210, an inner sleeve lower portion 220, and a seal ring 230. The inner sleeve upper portion 210 has a through portion 211. The inner sleeve lower portion 220 has a through portion 221. In the inner sleeve 200, a through hole through which the lifter pin 15 is inserted is formed by the through portion 211 and the through portion 221. At least a portion of the inner sleeve upper portion 210 is inserted into the through hole 1113a of the outer sleeve 1113. The inner sleeve lower portion 220 is disposed across the inner sleeve contact portion 1110c2, the through hole 1116a of the lid member 1116, and the through hole 1120a of the support member 1120. The inner sleeve upper portion 210 and the inner sleeve lower portion 220 may be made of the same material or may be made of different materials. The seal ring 230 is disposed between a lower surface of the inner sleeve upper portion 210 and an upper surface of the inner sleeve lower portion 220. The seal ring 230 is, for example, an O-ring. The seal ring 230 has an annular shape and is made of a material that is resistant to a radical. For the seal ring 230, a fluorine-based material, such as vinylidene fluoride (FKM), polytetrafluoroethylene (PTFE), or tetrafluoroethylene-perfluoro vinyl ether (FFKM), can be used.

Here, the inner sleeve lower portion 220 is aligned in contact with the inner sleeve contact portion 1110c2 of the first through hole 1110c and guides the lifter pin 15 inserted through the through portion 221. Thereby, alignment accuracy of an axial position of the lifter pin 15 guided by the inner sleeve lower portion 220 can be improved. Therefore, the lifter pin 15 can be prevented from contacting the electrostatic chuck 1111 (the bottom surface of the electrostatic chuck 1111 and the wall surface of the second through hole 1111c).

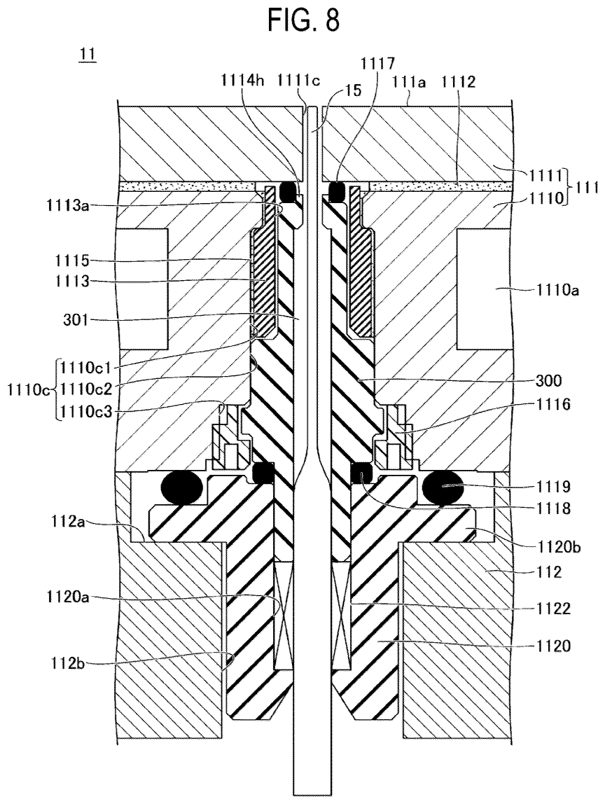

FIG. 8 is still another example of the cross-sectional view of the substrate support 11 around the lifter pin 15. The substrate support body 111 shown in FIG. 8 includes an inner sleeve 300 instead of the inner sleeve 1114 and the lifter pin guide 1121 shown in FIG. 2. The other configurations are the same, and a redundant description is omitted.

As shown in FIG. 8, the inner sleeve 300 may be formed by integrating the inner sleeve 1114 and lifter pin guide 1121 shown in FIG. 2.

The inner sleeve 300 has a through hole 301 through which the lifter pin 15 is inserted. Here, the inner sleeve 300 is aligned in contact with the inner sleeve contact portion 1110c2 of the first through hole 1110c and guides the lifter pin 15. Thereby, alignment accuracy of an axial position of the lifter pin 15 guided by the inner sleeve 300 can be improved. Therefore, the lifter pin 15 can be prevented from contacting the electrostatic chuck 1111 (the bottom surface of the electrostatic chuck 1111 and the wall surface of the second through hole 1111c).

In FIGS. 2 to 8, the configuration in which the through holes (the second through hole 1111c and the first through hole 1110c) formed in the substrate support body 111 are through holes through which the lifter pin 15 is inserted have been described by way of example. However, the configuration of the through holes is not limited thereto. The through holes may be applied to the through hole formed in the substrate support body 111 as the gas supply path 51 (see FIG. 1) that supplies a heat transfer gas to the gap between the rear surface of the substrate W and the central region 111a.

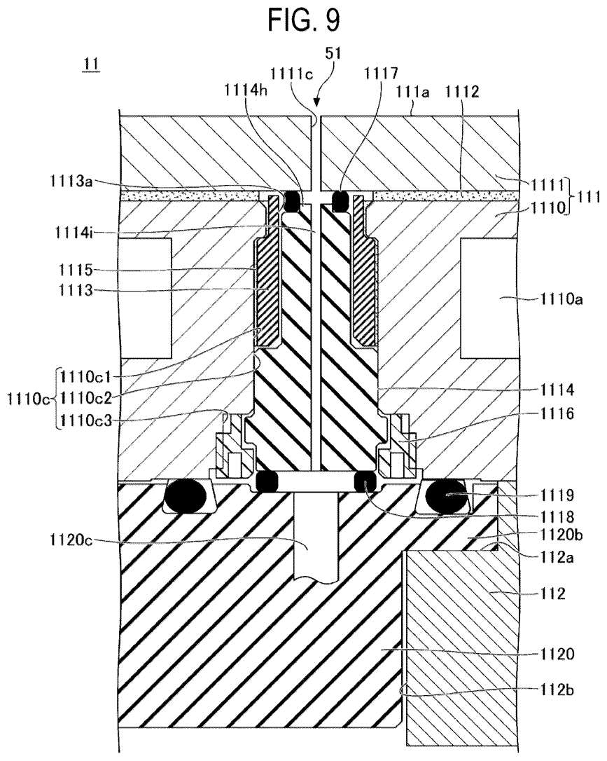

FIG. 9 is an example of a cross-sectional view of the substrate support 11 around the gas supply path 51. Here, the inner sleeve 1114 has a through hole 1114i through which gas flows. Further, in the support member 1120, a gas flow path 1120c is formed. The gas supply path 51 includes the gas flow path 1120c formed in the support member 1120, the through hole 1114i formed in the inner sleeve 1114 disposed in the first through hole 1110c of the base 1110, and the second through hole 1111c of the electrostatic chuck 1111. In this way, the structure of the outer sleeve 1113, the inner sleeve 1114, the lid member 1116, and the seal rings 1117 and 1118, and the seal ring 1119 may be applied to the gas supply path 51. The other configurations are the same, and a redundant description is omitted.

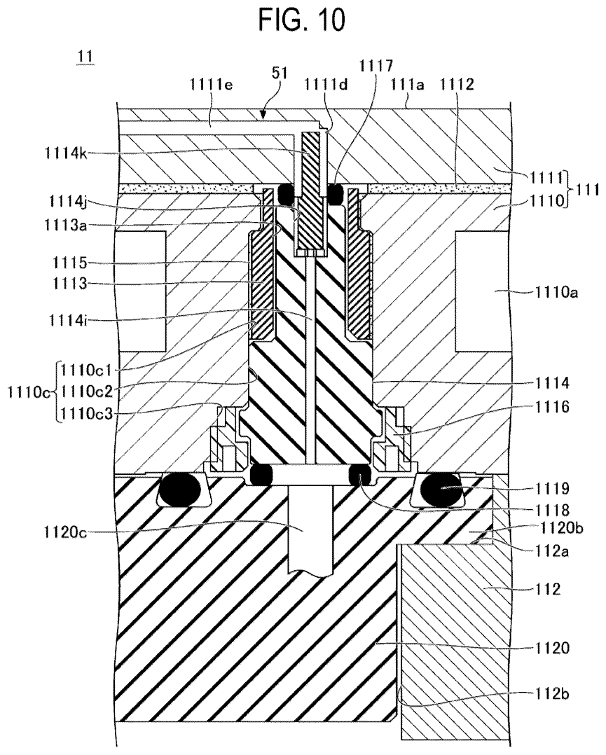

FIG. 10 is another example of the cross-sectional view of the substrate support 11 around the gas supply path 51. Here, the inner sleeve 1114 has the through hole 1114i through which gas flows. Further, in the support member 1120, the gas flow path 1120c is formed. The gas supply path 51 includes the gas flow path 1120c formed in the support member 1120, the through hole 1114i formed in the inner sleeve 1114 disposed in the first through hole 1110c of the base 1110, and gas flow paths 1111d and 1111e formed in the electrostatic chuck 1111. Here, the second through hole of the electrostatic chuck 1111 is formed by the gas flow path 1111d formed from the lower surface of the electrostatic chuck 1111, the gas flow path 1111e that communicates with the gas flow path 1111d and is installed horizontally, and a gas flow path (not shown) formed up to a substrate placement surface. The other configurations are the same, and a redundant description is omitted.

Furthermore, a recess 1114j communicating with the through hole 1114i is formed on an upper surface of the inner sleeve 1114. An embedded member 1114k for suppressing or preventing abnormal discharge is inserted into the recess 1114j. The embedded member 1114k is disposed from the first through hole 1110c of the base 1110 to the second through hole (gas flow path 1111d) of the electrostatic chuck 1111.

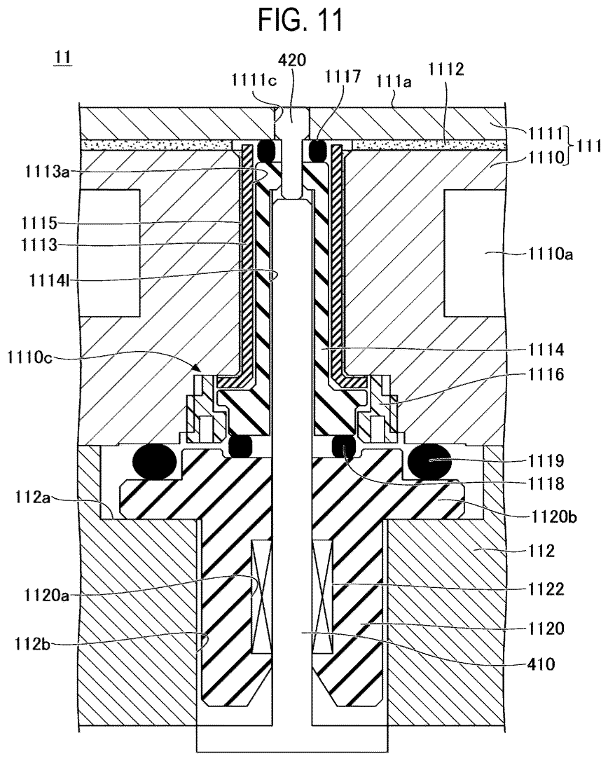

FIG. 11 is an example of a cross-sectional view of the substrate support 11 around a sensor. As shown in FIG. 11, the inner sleeve 1114 has a through hole 11141 through which a sensor support 410 and a sensor 420 are inserted. The sensor support 410 and the sensor 420 are disposed in a through hole that penetrates the substrate support 11. The structure of the outer sleeve 1113, the inner sleeve 1114, the lid member 1116, and the seal rings 1117 and 1118, and the sealing ring 1119 may be applied to the through hole in which the sensor support 410 and the sensor 420 are disposed similarly to the through hole (see FIG. 2, etc.) in which the lifter pin 15 is disposed. The other configurations are the same, and a redundant description is omitted.

In FIGS. 2 to 11, the through hole formed in the substrate support surface, which is the central region 111a of the substrate support body 111 has been described by way of example. However, the configuration of the through hole is not limited thereto. Similarly, the structure of the outer sleeve 1113, the inner sleeve 1114, the lid member 1116, the seal rings 1117 and 1118, and the seal ring 1119 may be applied even to the through hole formed in the ring support surface, which is the annular region 111b of the substrate support body 111.

Further, while the sleeve disposed in the first through hole 1110c of the base 1110 has been described as having a double structure of the outer sleeve 1113 and the inner sleeve 1114, the structure of the sleeve is not limited thereto. In the sleeve, the outer sleeve 1113 may be omitted and only the inner sleeve 1114 may be used.

The embodiments disclosed above include, for example, the following aspects.

### Supplementary Note 1

According to an aspect of the above-described technique, there is provided a plasma processing apparatus, including a plasma processing chamber, a base support disposed within the plasma processing chamber, a base having a first through hole penetrating from an upper surface of the base to a lower surface of the base and disposed on an upper portion of the base support, an electrostatic chuck having a second through hole communicating with the first through hole by penetrating from a substrate support surface or a ring support surface to a lower surface of the electrostatic chuck and disposed on an upper portion of the base, a first insulating member having a cylindrical shape and disposed within the first through hole, a second insulating member having a cylindrical shape and disposed within the first through hole to surround at least a portion of the first insulating member, a first sealing member disposed between the first insulating member and the electrostatic chuck, and a second sealing member disposed between the first insulating member and an insulating support member disposed within the base support.

### Supplementary Note 2

In the plasma processing apparatus of Supplementary Note 1, the first insulating member includes a first portion having a first outer diameter and a second portion having a second outer diameter larger than the first outer diameter and disposed below the first portion, and the second insulating member is disposed to surround the first portion.

### Supplementary Note 3

In the plasma processing apparatus of Supplementary Note 2, the first insulating member is disposed within the first through hole such that the second portion and an inner circumferential surface of the first through hole are in contact with each other.

### Supplementary Note 4

In the plasma processing apparatus of any one of Supplementary Notes 1 to 3, the plasma processing apparatus further includes an adhesive layer provided between the base and the electrostatic chuck.

### Supplementary Note 5

In the plasma processing apparatus of any one of Supplementary Notes 1 to 4, the first insulating member has at least one protrusion configured to be in contact with the first sealing member to align the first sealing member.

### Supplementary Note 6

In the plasma processing apparatus of Supplementary Note 5, the at least one protrusion is a plurality of protrusions installed in a circumferential direction, and a space is provided between each of the protrusions.

### Supplementary Note 7

In the plasma processing apparatus of Supplementary Note 6, the first sealing member has an annular shape, and the protrusions are in contact with an inner circumference of the first sealing member.

### Supplementary Note 8

In the plasma processing apparatus of any one of Supplementary Notes 1 to 7, the plasma processing apparatus further includes a cylindrical lid member having a male thread portion configured to screw into a female thread portion formed in the first through hole.

### Supplementary Note 9

In the plasma processing apparatus of Supplementary Note 8, the female thread portion is alumite-processed, and the lid member is made of a resin material.

### Supplementary Note 10

In the plasma processing apparatus of any one of Supplementary Notes 1 to 9, the plasma processing apparatus includes a lifter pin inserted through the first through hole and the second through hole, and a lifter pin guide configured to guide the lifter pin, and the first insulating member has a fitting portion configured to fit with the lifter pin guide.

### Supplementary Note 11

In the plasma processing apparatus of any one of Supplementary Notes 1 to 10, comprising a third sealing member disposed between the base and the support member.

### Supplementary Note 12

According to another aspect of the above-described technique, there is provided a substrate support body, including a base having a first through hole penetrating from an upper surface of the base to a lower surface of the base, an electrostatic chuck having a second through hole communicating with the first through hole by penetrating from a substrate support surface or a ring support surface to a lower surface of the electrostatic chuck and disposed on an upper portion of the base, a first insulating member having a cylindrical shape and disposed within the first through hole, a second insulating member having a cylindrical shape and disposed within the first through hole to surround at least a portion of the first insulating member, and a first sealing member disposed between the first insulating member and the electrostatic chuck.

### Supplementary Note 13

In the substrate support body of Supplementary Note 12, the first insulating member includes a first portion having a first outer diameter, and a second portion having a second outer diameter larger than the first outer diameter and disposed below the first portion, and the second insulating member is disposed to surround the first portion.

### Supplementary Note 14

In the substrate support body of Supplementary Note 13, the first insulating member is disposed within the first through hole such that the second portion and an inner circumferential surface of the first through hole are in contact with each other.

### Supplementary Note 15

In the substrate support body of any one of Supplementary Notes 12 to 14, the substrate support body further includes an adhesive layer provided between the base and the electrostatic chuck.

### Supplementary Note 16

In the substrate support body of any one of Supplementary Notes 12 to 15, the first insulating member has at least one protrusion configured to be contact with the first sealing member to align the first sealing member.

### Supplementary Note 17

In the substrate support body of Supplementary Note 16, the at least one protrusion is a plurality of protrusions installed in a circumferential direction, and a space is provided between each of the protrusions.

### Supplementary Note 18

In the substrate support body of Supplementary Note 17, the first sealing member has an annular shape, and the protrusions are in contact with an inner circumference of the first sealing member.

### Supplementary Note 19

In the substrate support body of any one of Supplementary Notes 12 to 18, the substrate support body further includes a cylindrical lid member having a male thread portion configured to screw into a female thread portion formed in the first through hole.

### Supplementary Note 20

In the substrate support body of Supplementary Note 19, the female thread portion is alumite-processed, and the lid member is made of a resin material.

The present application claims priority based on United States Patent Application No. 63/257,705 filed on Oct. 20, 2021, the disclosure of which is incorporated herein in its entirety by reference. In addition, the present application claims priority based on Japanese Patent Application No. 2022-117497 filed on Jul. 22, 2022, the disclosure of which is incorporated herein in its entirety by reference.

According to the present disclosure in some embodiments, it is possible to provide a plasma processing apparatus and a substrate support body capable of relieving a filling rate of a sealing member.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a plasma processing chamber;
a base support disposed within the plasma processing chamber;
a base having a first through hole penetrating from an upper surface of the base to a lower surface of the base and disposed on an upper portion of the base support;
an electrostatic chuck having a second through hole communicating with the first through hole by penetrating from a substrate support surface or a ring support surface to a lower surface of the electrostatic chuck and disposed on an upper portion of the base;
a first insulating member having a cylindrical shape and disposed within the first through hole;
a second insulating member having a cylindrical shape and disposed within the first through hole to surround at least a portion of the first insulating member;
a first sealing member disposed between the first insulating member and the electrostatic chuck; and
a second sealing member disposed between the first insulating member and an insulating support member disposed within the base support.

2. The plasma processing apparatus of claim 1, wherein the first insulating member includes:
a first portion having a first outer diameter; and
a second portion having a second outer diameter larger than the first outer diameter and disposed below the first portion, and
wherein the second insulating member is disposed to surround the first portion.

3. The plasma processing apparatus of claim 2, wherein the first insulating member is disposed within the first through hole such that the second portion and an inner circumferential surface of the first through hole are in contact with each other.

4. The plasma processing apparatus of claim 3, further comprising an adhesive layer provided between the base and the electrostatic chuck.

5. The plasma processing apparatus of claim 4, wherein the first insulating member has at least one protrusion configured to be in contact with the first sealing member to align the first sealing member.

6. The plasma processing apparatus of claim 5, wherein the at least one protrusion is a plurality of protrusions installed in a circumferential direction, and a space is provided between each of the protrusions.

7. The plasma processing apparatus of claim 6, wherein the first sealing member has an annular shape, and
wherein the protrusions are in contact with an inner circumference of the first sealing member.

8. The plasma processing apparatus of claim 1, further comprising a cylindrical lid member having a male thread portion configured to screw into a female thread portion formed in the first through hole.

9. The plasma processing apparatus of claim 8, wherein the female thread portion is alumite-processed, and
wherein the lid member is made of a resin material.

10. The plasma processing apparatus of claim 1, further comprising:
a lifter pin inserted through the first through hole and the second through hole; and
a lifter pin guide configured to guide the lifter pin,
wherein the first insulating member has a fitting portion configured to fit with the lifter pin guide.

11. The plasma processing apparatus of claim 1, further comprising a third sealing member disposed between the base and the insulating support member.

12. A substrate support body, comprising:
a base having a first through hole penetrating from an upper surface of the base to a lower surface of the base;
an electrostatic chuck having a second through hole communicating with the first through hole by penetrating from a substrate support surface or a ring support surface to a lower surface of the electrostatic chuck and disposed on an upper portion of the base;
a first insulating member having a cylindrical shape and disposed within the first through hole;
a second insulating member having a cylindrical shape and disposed within the first through hole to surround at least a portion of the first insulating member; and
a first sealing member disposed between the first insulating member and the electrostatic chuck.

13. The substrate support body of claim 12, wherein the first insulating member includes:
a first portion having a first outer diameter; and
a second portion having a second outer diameter larger than the first outer diameter and disposed below the first portion, and
wherein the second insulating member is disposed to surround the first portion.

14. The substrate support body of claim 13, wherein the first insulating member is disposed within the first through hole such that the second portion and an inner circumferential surface of the first through hole are in contact with each other.

15. The substrate support body of claim 14, further comprising an adhesive layer provided between the base and the electrostatic chuck.

16. The substrate support body of claim 15, wherein the first insulating member has at least one protrusion configured to be contact with the first sealing member to align the first sealing member.

17. The substrate support body of claim 16, wherein the at least one protrusion is a plurality of protrusions installed in a circumferential direction, and a space is provided between each of the protrusions.

18. The substrate support body of claim 17, wherein the first sealing member has an annular shape, and
wherein the protrusions are in contact with an inner circumference of the first sealing member.

19. The substrate support body of claim 12, further comprising a cylindrical lid member having a male thread portion configured to screw into a female thread portion formed in the first through hole.

20. The substrate support body of claim 19, wherein the female thread portion is alumite-processed, and
wherein the lid member is made of a resin material.
